(19) United States
(12) Patent Application Publication
(10) Pub. No.: US 2026/0076151 A1
(43) Pub. Date: Mar. 12, 2026

(54) LASER PROCESSING DEVICE AND LASER PROCESSING METHOD

(71) Applicant: IBIDEN CO., LTD., Ogaki (JP)

(72) Inventors: Kohei SUZUKI, Ogaki (JP); Takumi INAGAKI, Ogaki (JP); Osamu INAGAWA, Ogaki (JP)

(73) Assignee: IBIDEN CO., LTD., Ogaki (JP)

(21) Appl. No.: 19/255,069

(22) Filed: Jun. 30, 2025

(30) Foreign Application Priority Data
Jul. 1, 2024 (JP) 2024-106271

(51) Int. Cl. H01L 21/66; B23K 26/03; B23K 26/04; B23K 26/06; B23K 26/402; B23K 103/00; H01L 21/48; H01L 21/67; H01L 23/498

(52) U.S. Cl. CPC H10P 74/238; B23K 26/032; B23K 26/04; B23K 26/0648; B23K 26/402; H10P 72/0436; H10P 72/0604; H10W 70/05; H10W 70/685; B23K 2103/42

(57) ABSTRACT

A laser processing device for forming an opening in an insulating layer of a wiring substrate includes a light source that emits a laser beam, an objective lens that focuses the laser beam onto a surface of a wiring substrate, a control device including circuitry that control irradiation of the laser beam, and a sensor that outputs to the control device a sensor output based on plasma light emitted from the wiring substrate irradiated with the laser beam. The circuitry of the control device calculates an integrated value from start of processing at one processing position for the sensor output corresponding to each of irradiations of the laser beam at the one processing position on the wiring substrate and terminates formation of the opening at the one processing position when the integrated value satisfies a predetermined condition.

### CROSS-REFERENCE TO RELATED APPLICATIONS

The present application is based upon and claims the benefit of priority to Japanese Patent Application No. 2024-106271, filed Jul. 1, 2024, the entire contents of which are incorporated herein by reference.

### BACKGROUND OF THE INVENTION

### Field of the Invention

The present invention relates to a laser processing device and a laser processing method.

### Description of Background Art

Japanese Patent Application Laid-Open Publication No. 2013-43198 describes a drilling method and a laser processing device for forming a laser-processed hole. The entire contents of this publication are incorporated herein by reference.

### SUMMARY OF THE INVENTION

According to one aspect of the present invention, a laser processing device for forming an opening in an insulating layer of a wiring substrate includes a light source that emits a laser beam, an objective lens that focuses the laser beam onto a surface of a wiring substrate, a control device including circuitry that control irradiation of the laser beam, and a sensor that outputs to the control device a sensor output based on plasma light emitted from the wiring substrate irradiated with the laser beam. The circuitry of the control device calculates an integrated value from start of processing at one processing position for the sensor output corresponding to each of irradiations of the laser beam at the one processing position on the wiring substrate and terminates formation of the opening at the one processing position when the integrated value satisfies a predetermined condition.

According to another aspect of the present invention, a laser processing method for a wiring substrate includes irradiating an insulating layer of a wiring substrate with a laser beam such that an opening is formed in the insulating layer and exposes a portion of a conductor layer covered by the insulating layer, and causing a sensor to output a sensor output based on plasma light emitted from the wiring substrate irradiated with the laser beam. The irradiating includes repeating irradiation of the laser beam multiple times at one processing position on the wiring substrate, calculating an integrated value from a start of processing at one processing position for the sensor output corresponding to the irradiation of each of the times, and terminating formation of the opening at the one processing position when the integrated value satisfies a predetermined condition.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic diagram illustrating an example of an overall structure of a laser processing device according to an embodiment of the present invention;

FIG. 2 is a cross-sectional view illustrating an example of a wiring substrate processed using a laser processing device and method according to embodiments of the present invention;

FIG. 3 is a cross-sectional view illustrating an example of a processing state by a laser processing device and method according to embodiments of the present invention;

FIG. 4A is a cross-sectional view illustrating an example of a progress state of processing by a laser processing device and method according to embodiments of the present invention;

FIG. 4B is a cross-sectional view illustrating an example of a progress state of processing by a laser processing device and method according to embodiments of the present invention;

FIG. 5 illustrates an example of frequency characteristics of filters in a laser processing device according to an embodiment of the present invention;

FIG. 6A shows an example of measurement results of sensor outputs of a laser processing device according to an embodiment of the present invention;

FIG. 6B shows an example of measurement results of sensor outputs of a laser processing device according to an embodiment of the present invention;

FIG. 6C shows an example of measurement results of sensor outputs of a laser processing device according to an embodiment of the present invention;

FIG. 6D shows an example of measurement results of sensor outputs of a laser processing device according to an embodiment of the present invention;

FIG. 7A is an observation image of an opening formed at the time when the measurement results of FIG. 6A were obtained;

FIG. 7B is an observation image of an opening formed at the time when the measurement results of FIG. 6B were obtained;

FIG. 7C is an observation image of an opening formed at the time when the measurement results of FIG. 6C were obtained;

FIG. 7D is an observation image of an opening formed at the time when the measurement results of FIG. 6D were obtained; and

FIG. 8 shows investigation results of correlation between a sensor output integrated value and an opening area of an opening in a laser processing device according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

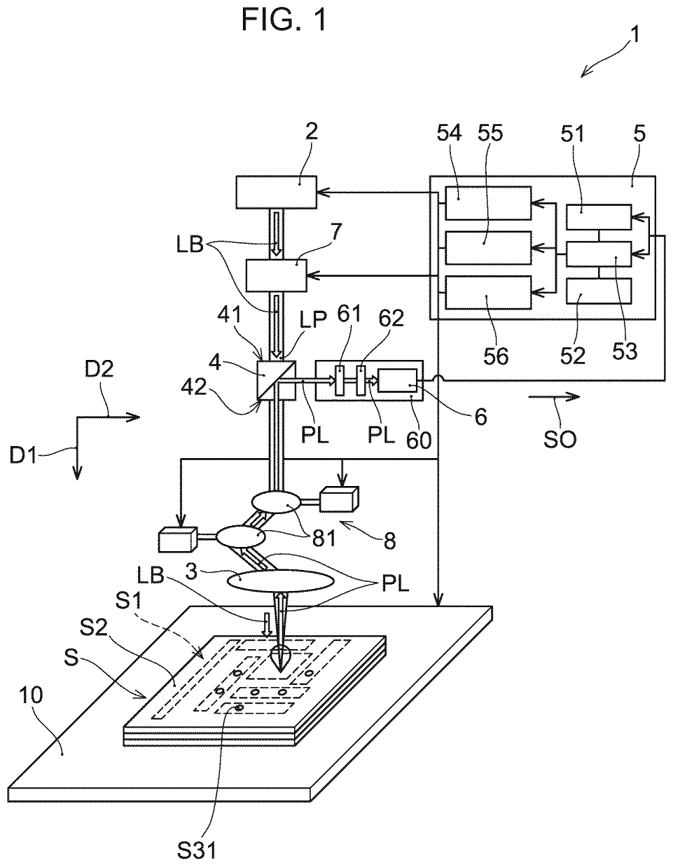

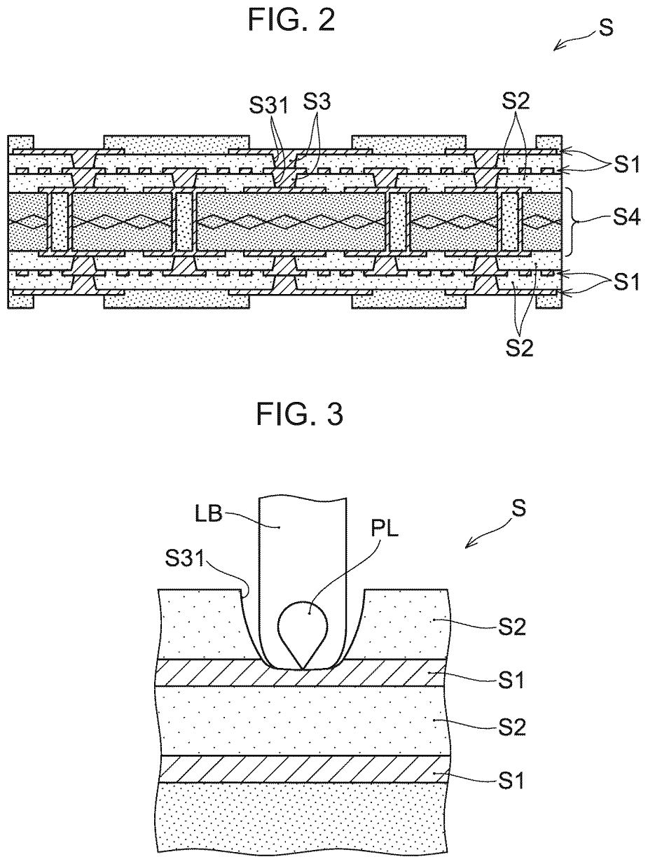

FIG. 1 schematically illustrates an overall structure of a laser processing device 1, which is an example of the laser processing device according to the embodiment. FIG. 2 illustrates a cross-sectional view of a wiring substrate (S), which is an example of a processing target according to the laser processing device and laser processing method of the embodiment. Further, FIG. 3 illustrates an example of a processing state at an irradiation spot of a laser beam according to the laser processing device and laser processing method of the embodiment. The laser processing device 1 in FIG. 1 is merely one example of the laser processing device of the embodiment. The laser processing device of the embodiment may include any additional structural elements and/or functional blocks in addition to those included in the laser processing device 1 in FIG. 1, and may omit some of the structural elements included in the laser processing device 1. Further, a wiring substrate processed by the laser processing device and laser processing method of the embodiment may have any structure different from the structure of the wiring substrate (S) illustrated in FIG. 2. The laser processing device and laser processing method of the embodiment can be applied to a wiring substrate having any structure that includes at least one conductor layer and one insulating layer covering the conductor layer.

### Structure of Laser Processing Device

As illustrated in FIG. 1, the laser processing device 1 includes a light source 2 that emits a laser beam (LB), an objective lens 3 that focuses the laser beam (LB), a control device 5 that controls irradiation of the laser beam (LB), and a sensor 6 that detects incident light and outputs an output (sensor output (SO)) according to the incident light. The laser processing device 1 in FIG. 1 further includes a beam splitter 4, an acousto-optic modulator (AOM) 7 that modulates the laser beam (LB) emitted from the light source 2 by an acousto-optic effect, a galvanometer mirror unit 8, a table 10, and two filters (61, 62). In the laser processing device 1 of FIG. 1, a processing target is the wiring substrate (S), and the objective lens 3 focuses the laser beam (LB) onto a surface of the wiring substrate (S).

The light source 2 is composed of any laser oscillator capable of emitting a laser beam (LB). The light source 2 may emit a pulsed laser beam (LB). As an example, the light source 2 emits a UV laser beam with a wavelength of 355 nm, which is a third harmonic of a UV YAG laser. Since a UV laser beam has excellent linearity and is suitable for forming a minute opening (S31), it may be preferable as the laser beam (LB) used in the laser processing device 1 of the embodiment. However, the laser beam (LB) is not limited to a UV laser beam and may be a laser beam of any wavelength capable of drilling a hole in the wiring substrate (S).

The AOM 7 performs deflection and/or intensity modulation on the laser beam (LB) emitted from the light source 2 according to characteristics such as a frequency and/or an amplitude of a high-frequency control signal transmitted from the control device 5. The AOM 7 may start or stop the irradiation of the laser beam (LB) onto the wiring substrate (S) by starting or stopping the deflection or modulation operation according to a control signal transmitted from the control device 5.

The galvanometer mirror unit 8 includes a pair of reflecting mirrors 81 and driving units that rotate the reflecting mirrors 81. The driving units respectively rotate the two reflecting mirrors 81 around respective rotation axes orthogonal to each other in response to control signals transmitted from the control device 5. The pair of reflecting mirrors 81, rotated to a desired orientation, deflects the laser beam (LB) in a desired direction. An irradiation position of the laser beam (LB) on the wiring substrate (S) can be finely adjusted.

The objective lens 3 causes the laser beam (LB) incident on the objective lens 3 from the galvanometer mirror unit 8 to be incident perpendicularly onto the surface of the wiring substrate (S), which is the processing target, and focuses the laser beam (LB) at that incident position. That is, the objective lens 3 functions as a so-called fθ lens. Any optical lens capable of focusing the laser beam (LB) at the incident position of the laser beam (LB) on the surface of the wiring substrate (S) can be used as the objective lens 3.

The table 10 supports the wiring substrate (S) placed on the table 10 for the formation of the opening (S31). The table 10 moves, for example, reciprocally in two mutually orthogonal directions, thereby moving the wiring substrate (S) relative to the irradiated laser beam (LB). As an example, the table 10 may be an XY table, but may be any movable table capable of positioning any position on the wiring substrate (S) to the irradiation position of the laser beam (LB). The movement of the table 10 is preferably controlled by the control device 5.

The wiring substrate (S) illustrated in FIG. 2 includes a core substrate (S4), and conductor layers (S1) and insulating layers (S2) that are alternately laminated on both sides of the core substrate (S4). Each conductor layer (S1) is covered by an insulating layer (S2) laminated on the side opposite to the core substrate (S4) with respect to the conductor layer (S1). The conductor layers (S1) are formed of, for example, copper, but may be formed of any metal other than copper. As an example, the insulating layers (S2) are formed mainly of an epoxy resin, but may also be formed mainly of, for example, a thermosetting resin other than an epoxy resin, such as a bismaleimide triazine resin (BT resin), or a thermoplastic resin such as a fluororesin. Each insulating layer (S2) has via conductors (S3) formed therein that connect the conductor layers sandwiching the insulating layer (S2). The via conductors (S3) are formed in openings (S31) that penetrate the insulating layer (S2). By the laser processing device 1 of the embodiment and the laser processing method of the embodiment, openings such as the openings (S31) illustrated in FIGS. 1 and 2, which penetrate the insulating layers of the wiring substrate and expose portions of the conductor layers covered by the insulating layers, are formed in the insulating layers.

When the surface of the wiring substrate (S) is irradiated with the laser beam (LB), as illustrated in FIG. 3, a plasma state is generated at the irradiation spot due to temperature rise and ionization, and plasma light (PL) is emitted. For example, as illustrated in FIG. 3, when the laser beam (LB) irradiates a conductor layer (S1), plasma light (PL) primarily containing a wavelength specific to the material (for example, copper) constituting the conductor layer (S1) is emitted.

In the laser processing device 1 of the embodiment, the beam splitter 4 is positioned in an optical path (LP) of the laser beam (LB) between the light source 2 and the objective lens 3. The beam splitter 4 transmits the laser beam (LB) incident on the first light input/output surface 41 from the light source 2 side to the objective lens 3 side, that is, the wiring substrate (S) side. Further, the beam splitter 4 reflects the plasma light (PL) incident on a second light input/output surface 42, which is on the opposite side with respect to the first light input/output surface 41, so that the plasma light (PL) deviates from the optical path (LP) of the laser beam (LB). That is, the beam splitter 4 reflects the plasma light (PL) emitted from the wiring substrate (S) due to the irradiation of the laser beam (LB) and incident from the wiring substrate (S) side in a direction different from both a propagation direction of the laser beam (LB) and the opposite direction thereof.

The beam splitter 4 in FIG. 1 reflects the incident plasma light (PL) to a second direction (D2) different from a first direction (D1) along the optical path (LP) of the laser beam (LB). Further, the beam splitter 4 may reflect only light of at least a specific wavelength among the incident plasma light (PL) to the second direction (D2). As an example, the beam splitter 4 may reflect light of a specific wavelength among the plasma light (PL) incident on the second light input/output surface 42 in the second direction (D2), which forms an angle of substantially 90 degrees with the first direction (D1). The beam splitter 4 may be a dichroic beam splitter that transmits or reflects light of a specific wavelength incident on each light input/output surface.

A wavelength band of light that the beam splitter 4 transmits from the first light input/output surface 41 side to the second light input/output surface 42 side may include, for example, 355 nm, which is the wavelength of UV laser. Further, the specific wavelength of light that is among the plasma light (PL) incident on the second light input/output surface 42 and is reflected by the beam splitter 4 to the second direction (D2) may be the wavelength of plasma light emitted by a conductor layer (S1) of the wiring substrate (S) due to irradiation by the laser beam (LB). For example, the specific wavelength may be a wavelength in a range of 230 to 326 nm of plasma light emitted when the laser beam (LB) irradiates copper.

The beam splitter 4 may transmit light of a wavelength different from the wavelength of the light reflected in the second direction (D2) among the plasma light (PL) incident on the second light input/output surface 42 to the first light input/output surface 41 side. A wavelength band of light that the beam splitter 4 transmits to the first light input/output surface 41 side among the plasma light (PL) incident on the second light input/output surface 42 may include the wavelength of plasma light emitted by a constituent material of the wiring substrate (S) other than a conductor layer (S1) due to irradiation by the laser beam (LB). For example, even when a resin such as an epoxy resin constituting the insulating layers (S2), glass used as a reinforcing material, or materials such as silicon oxide or alumina constituting particles added to the insulating layers (S2) emit plasma light, incidence of the plasma light to the sensor 6 can be prevented. A wavelength band of light that the beam splitter 4 transmits from the second light input/output surface 42 to the first light input/output surface 41 side may be, for example, a wavelength band of 336 to 1200 nm.

The beam splitter 4 may reflect light of all wavelengths among the plasma light (PL) incident on the second light input/output surface 42 to the second direction (D2). Even when the plasma light (PL) is reflected in this manner, as will be described later, by providing the filter 61 and/or filter 62, only light of a desired wavelength among the plasma light (PL) can be incident on the sensor 6.

In the laser processing device 1 of FIG. 1, a sensor unit 60 is constituted by the sensor 6, the filter 61, and the filter 62. The sensor unit 60 is positioned in the second direction (D2) such that the plasma light (PL) reflected by the beam splitter 4 toward the second direction (D2) enters the sensor unit 60. The filter 61 and the filter 62 are provided between the beam splitter 4 and the sensor 6. Light of a specific wavelength band among the light reflected by the beam splitter 4 toward the second direction (D2) passes through the filter 61 and the filter 62 and enters the sensor 6.

The sensor 6 outputs a sensor output (SO) to the control device 5 based on the plasma light (PL) reflected by the beam splitter 4 in the second direction (D2). Specifically, the sensor 6 detects light that reaches the sensor 6 among the plasma light (PL) reflected by the beam splitter 4. The sensor 6 outputs a sensor output (SO), which is an electrical signal having, for example, a level or frequency corresponding to an intensity of the detected light. As an example, the sensor 6 may be a photomultiplier tube capable of detecting light with high sensitivity and high speed. However, the sensor 6 may be any photoelectric conversion element, such as a photodiode or phototransistor, capable of outputting an electrical signal with characteristics corresponding to the intensity of the incident light. As an example, the “intensity” of light such as the plasma light (PL) can be the energy of light flowing through a unit area per unit time (Poynting vector or power density).

The control device 5 is, for example, constituted by an integrated circuit device (IC), such as a microcomputer, a programmable logic device, or a field-programmable gate array, that executes a predetermined operation according to a command of an embedded program. The control device 5 may also be constituted by any of these ICs and its peripheral components. An IC, such as a microcomputer, and its peripheral components, which constitute the control device 5, function as an arithmetic part 51, a determination part 53, an irradiation start/stop control part 54, an irradiation condition control part 55, and an irradiation position control part 56, which are included in the control device 5, according to an algorithm of a sequentially executed program (execution program). In the example of FIG. 1, the control device 5 further includes a storage part 52 that stores a predetermined threshold for the sensor output (SO) output by the sensor 6.

The arithmetic part 51 performs a predetermined calculation commanded by the execution program, for example, a calculation on the sensor output (SO), and outputs a calculation result to the determination part 53. As one function, the arithmetic part 51 is structured to calculate an integrated value for sensor outputs (SO) that respectively correspond to multiple irradiations of a pulsed laser beam (LB) to one processing position on the wiring substrate (S), which is the processing target, from the start of processing at that one processing position. This integrated value is hereinafter also simply referred to as the “sensor output integrated value.” As an example, the sensor output integrated value may be a simple sum of the sensor outputs (SO) from the start of processing at one processing position.

As one function, the determination part 53 determines whether or not the sensor output integrated value satisfies a predetermined condition set in advance for controlling the laser beam (LB). For example, the determination part 53 may compare the sensor output integrated value obtained by the calculation of the arithmetic part 51 with a predetermined threshold stored in the storage part 52 to determine whether or not the sensor output integrated value satisfies the predetermined condition. Then, the determination part 53 provides the determination result to the irradiation start/stop control part 54, the irradiation condition control part 55, and/or the irradiation position control part 56.

The irradiation start/stop control part 54 transmits a signal to control the start and stop of the emission of the laser beam (LB) by the light source 2 and/or the switching between on and off of the AOM 7 based on the determination result of the determination part 53. The irradiation condition control part 55 outputs a signal to control the energy density or power of the laser beam (LB) emitted by the light source 2 based on the determination result of the determination part 53. When the laser beam (LB) is emitted in a pulsed form, the irradiation condition control part 55 may output a signal to control the irradiation cycle or pulse width based on the determination result of the determination part 53. Further, the irradiation condition control part 55 may output a signal to control the degree of intensity modulation of the laser beam (LB) by the AOM 7 based on the determination result of the determination part 53. The irradiation position control part 56 outputs a signal to control the deflection of the laser beam (LB) by the AOM 7 and/or the galvanometer mirror unit 8, as well as the start, stop, and movement direction of the table 10, based on the determination result of the determination part 53.

The storage part 52 may be included in a microcomputer or the like primarily constituting the control device 5, or may be a memory device provided separately from an IC such as a microcomputer. The storage part 52 may store numerical values, time, counts, and conditional expressions related to predetermined conditions set in advance for the sensor output integrated value for controlling the laser beam (LB). As an example, the storage part 52 may store, for the sensor output integrated value, a “predetermined first threshold,” which will be described later.

In the formation of an opening (S31) in an insulating layer (S2) of the wiring substrate (S) by the laser processing device 1 of the embodiment, for example, a laser beam (LB) in the UV band and in a pulsed form, is emitted from the light source 2. The laser beam (LB) is modulated and/or deflected by the AOM 7, further deflected in a predetermined direction by the galvanometer mirror unit 8, and enters the objective lens 3. Then the laser beam (LB), focused by the objective lens 3, irradiates the surface of the wiring substrate (S) at a desired processing position. When the laser beam (LB) irradiates a conductor layer (S1), plasma light (PL) containing light of a wavelength specific to the constituent material of the conductor layer (S1) is emitted from the wiring substrate (S).

The plasma light (PL) passes through the objective lens 3 in a direction opposite to a propagation direction of the laser beam (LB), is further deflected by the galvanometer mirror unit 8, and enters the beam splitter 4 from the second light input/output surface 42. Among the plasma light (PL), at least the plasma light (PL) having the wavelength specific to the constituent material of the conductor layer (S1) is reflected by the beam splitter 4 in the second direction (D2). Among the plasma light (PL), the plasma light (PL) having the wavelength specific to the constituent material of the conductor layer (S1) enters the sensor 6. The sensor 6 outputs a sensor output (SO) having a level corresponding to, for example, the intensity of the incident light to the control device 5.

The control device 5 controls the stopping of the irradiation of the wiring substrate (S) by the laser beam (LB), the irradiation conditions of the laser beam (LB), and the irradiation position of the laser beam (LB), based on the sensor output (SO). In other words, the control device 5 performs control such as stopping the irradiation of the laser beam (LB), adjusting the irradiation conditions of the laser beam (LB) such as the energy density, pulse width, and irradiation cycle, or shifting the irradiation position of the laser beam (LB) from one irradiation position to the next irradiation position, based on the sensor output (SO). In particular, in the laser processing device 1 of the embodiment, the control device 5 is structured to control the irradiation of the laser beam (LB) based on the above-described sensor output integrated value.

Specifically, in the laser processing device 1 of the embodiment, the control device 5 calculates the sensor output integrated value, and when the sensor output integrated value satisfies a predetermined condition, terminates the formation of the opening (S31) by irradiation of the laser beam (LB) at the one processing position for which the sensor output integrated value is calculated. The “one processing position for which the sensor output integrated value is calculated” is the position in the wiring substrate (S) that is currently irradiated with the laser beam (LB) when the sensor output integrated value satisfies a predetermined condition during multiple irradiations of the laser beam (LB) to the same position. As an example, when the control device 5 recognizes that the integrated sensor output value satisfies a predetermined condition, the embedded program of a microcomputer or the like constituting the control device 5 may include a command to terminate the irradiation of the laser beam (LB) to the processing position to which the laser beam (LB) is being irradiated at that time, either immediately or after a predetermined time has elapsed.

In the following description, the description that “the control device 5 is structured to (perform a specific process)” includes the meaning that the execution program embedded in the microcomputer or the like constituting the control device 5 includes a command that causes the control device 5 to perform that specific process.

In the laser processing device of the embodiment, instead of stopping irradiation upon detecting a change in the plasma light spectrum or reaching a predetermined number of laser beam irradiations as in Patent Document 1, the formation of the opening (S31) at the processing position being irradiated with the laser beam (LB) is terminated when the sensor output integrated value satisfies a predetermined condition. Therefore, as described in detail below, it is thought that an opening (S31) with a bottom surface area closer to a desired opening area can be formed.

### Changes in Plasma Light

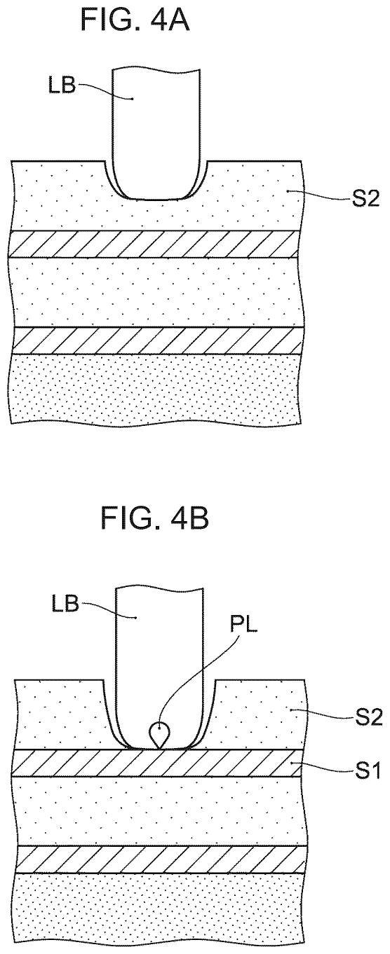

FIGS. 4A and 4B illustrate progress states of processing prior to the state illustrated in FIG. 3 in the laser processing device and laser processing method of the embodiment. The processing state of the irradiation site in the laser processing device and laser processing method of the embodiment changes in the order of the states illustrated in FIGS. 4A, 4B, and 3.

In the wiring substrate (S), which is the processing target, as the irradiation site of the laser beam (LB) changes from the insulating layer (S2) to an interface between the insulating layer (S2) and the conductor layer (S1), and then to the conductor layer (S1), the plasma light (PL) is emitted from the wiring substrate (S) when the conductor layer (S1) is irradiated with the laser beam (LB). For example, as illustrated in FIG. 4A, while the laser beam (LB) is irradiating the insulating layer (S2), substantially no plasma light is emitted. Even when plasma light is emitted, its intensity is minimal, and the faintly emitted plasma light contains substantially no wavelength specific to the material (for example, copper) constituting the conductor layer (S1).

Next, as illustrated in FIG. 4B, when the laser beam (LB) begins to irradiate the conductor layer (S1) at the interface between the insulating layer (S2) and the conductor layer (S1), the plasma light (PL) containing a wavelength specific to the constituent material of the conductor layer (S1) starts to be emitted.

Then, when the laser beam (LB) irradiates the conductor layer (S1) (see FIG. 3), plasma light (PL) primarily containing a wavelength specific to the material (for example, copper) constituting the conductor layer (S1) is emitted with a higher intensity than the plasma light (PL) emitted in the processing state illustrated in FIG. 4B.

That is, as the irradiation site transitions from the insulating layer (S2) to the conductor layer (S1), the intensity of the plasma light (PL) increases. Further, in the plasma light (PL), the component of a wavelength specific to the constituent material of the conductor layer (S1) increases. Therefore, the intensity of the plasma light (PL) entering the sensor 6 via the beam splitter 4 and the filters (61, 62) increases. Then, the level or frequency of the sensor output (SO) changes according to the photoelectric conversion characteristics of the sensor 6. Therefore, the “sensor output integrated value,” calculated by integrating the sensor output (SO) for each of multiple laser beam (LB) irradiations at the same location, is thought to increase with each irradiation of the laser beam (LB) as the irradiation site shifts to the conductor layer (S1).

Then, as described later, the sensor output integrated value has a specific relationship with the opening area at the bottom surface of the opening (S31) formed by the multiple laser beam (LB) irradiations for which the sensor output integrated value is calculated. Based on this specific relationship, in the laser processing device 1 of the embodiment, the control device 5 is structured to terminate the formation of the opening (S31) at the processing position being irradiated with the laser beam (LB) when the sensor output integrated value satisfies a predetermined condition.

For example, the control device 5 may terminate the formation of the opening (S31) at the processing position at that moment by immediately stopping the irradiation of the laser beam (LB) when the sensor output integrated value satisfies a predetermined condition. As another example, when the sensor output integrated value satisfies a predetermined condition, the control device 5 may continue the irradiation of the laser beam (LB) for a predetermined time to ensure the formation of an opening (S31) with a desired opening area and then stop the irradiation, thereby terminating the formation of the opening (S31) at the processing position at that moment.

As an example, the “predetermined condition” may be that the sensor output integrated value reaches a predetermined first threshold. In other words, the control device 5 may be structured to terminate the irradiation of the laser beam (LB) at the processing position being irradiated with the laser beam (LB) at that moment when the sensor output integrated value reaches a predetermined first threshold. The “predetermined first threshold” may be, for example, a value of the sensor output integrated value corresponding to a median of an allowable range for the opening area at the bottom surface of the opening (S31). By terminating the formation of the opening at the processing position being irradiated with the laser beam (LB) when the sensor output integrated value reaches the predetermined first threshold, it may be possible to form an opening with a bottom surface area close to a desired opening area.

As another example, the “predetermined condition” may be that a rate of increase in the sensor output integrated value due to one irradiation of the laser beam (LB) (hereinafter this rate of increase is also referred to as the “unit increase rate”) falls within a range of a predetermined second threshold. In this case, the “predetermined second threshold” may be, for example, 40% or more and 60% or less. The reason for this is that an excessively large unit increase rate may indicate that the laser beam (LB) has just begun to irradiate the conductor layer (S1), while an excessively small unit increase rate may indicate that the change in the formation state of the opening for each irradiation of the laser beam (LB) has become saturated.

### Filter Characteristics

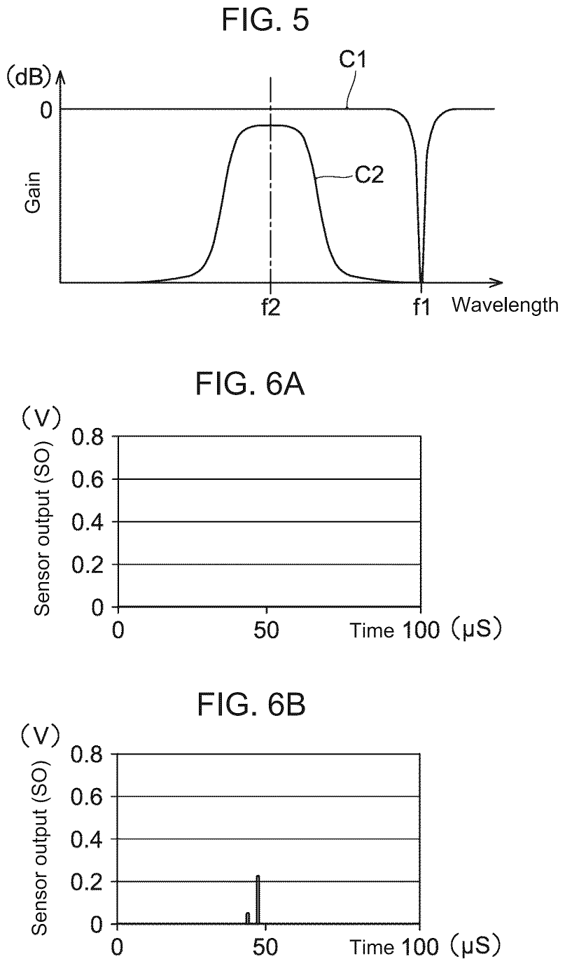

FIG. 5 illustrates an example of wavelength characteristics of gains (or attenuation rates) of the filter 61 and filter 62. The characteristics of the filter 61 are represented by a curve (C1), and the characteristics of the filter 62 are represented by a curve (C2). As illustrated in FIG. 5, the filter 61 may be a band-stop filter that significantly attenuates or blocks light in a specific wavelength band including a wavelength (f1). The filter 61 may also be a notch filter that significantly attenuates light in an extremely narrow wavelength band. The filter 61 may have a stop band that includes the wavelength of the laser beam (LB) emitted from the light source 2. When the filter 61 has such a stop band, even when a laser beam emitted from the light source unintentionally passes through or is reflected toward the sensor 6 (see FIG. 1), the laser beam is prevented from reaching the sensor 6 and being erroneously detected by the sensor 6. For example, when the light source emits a UV laser beam having a wavelength of 355 nm, the wavelength (f1) included in the stop band illustrated in FIG. 5 may be 355 nm.

On the other hand, as illustrated in FIG. 5, the filter 62 may be a bandpass filter that transmits only light in a specific wavelength band including a wavelength (f2) while attenuating or blocking light in other wavelength bands. The filter 62 preferably transmits only light in a wavelength band of plasma light emitted by a conductor layer of the wiring substrate. which is the processing target, due to irradiation by a laser beam from the light source. For example, the wavelength band of light transmitted by the filter 62 may be a wavelength band of plasma light emitted when a laser beam from the light source irradiates copper. Therefore, the wavelength (f2) included in the passband illustrated by the curve (C2) in FIG. 5 may be 326 nm.

### Sensor Output Measurement Example and Opening Observation Example

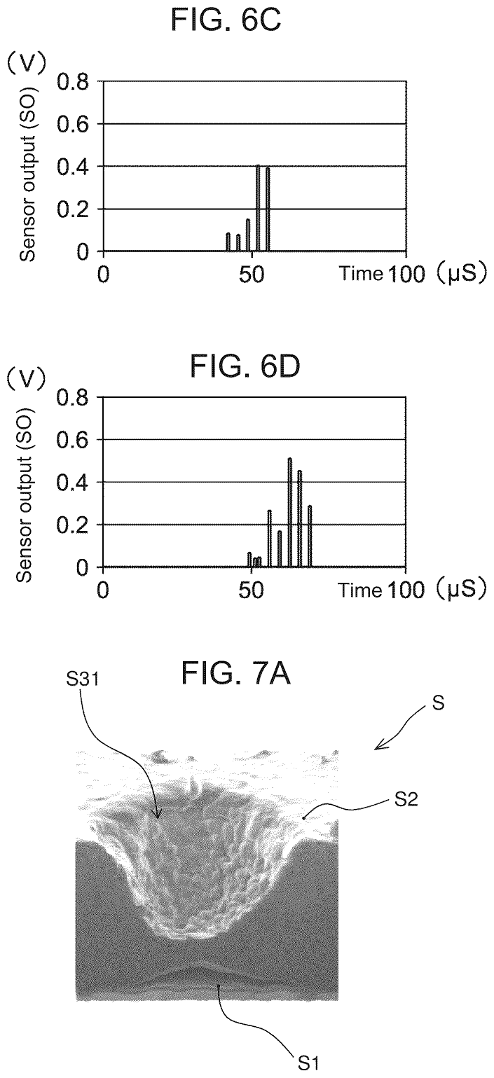

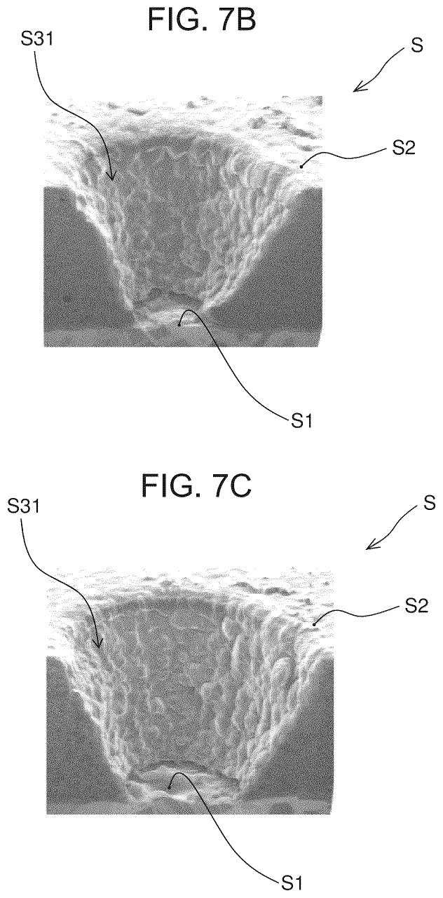

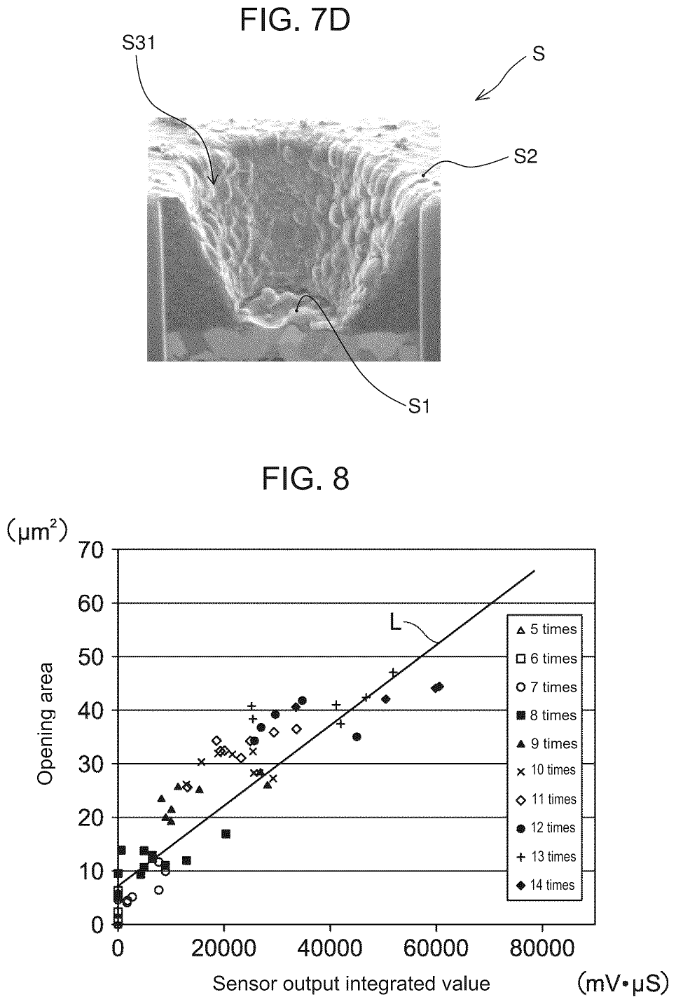

FIGS. 6A to 6D show measurement examples of sensor outputs (SO) obtained by forming an opening in an insulating layer of a wiring substrate using the laser processing device 1 of the embodiment illustrated in FIG. 1. In FIGS. 6A to 6D, the vertical axis represents the level (voltage) of the sensor output (SO) measured for each irradiation when a pulsed laser beam was repeatedly irradiated on the same location of the wiring substrate in a plan view. In FIGS. 6A to 6D, the horizontal axis is the time axis, showing progression of time with the repeated irradiation of the laser beam. The height of each vertical bar shown at each point on the horizontal axis indicates the level of the sensor output (SO) measured for one pulsed laser beam irradiation at that point in time. Further, each opening already formed at the time the measurement results shown in FIGS. 6A to 6D were obtained was cut along its axial direction and observed from an oblique angle above the opening. The images obtained from these observations are shown in FIGS. 7A to 7D. The observation images in FIGS. 7A to 7D respectively correspond to the openings formed by the laser beam irradiations for which the sensor output measurement results are shown in FIGS. 6A to 6D. As is evident from the cross-sectional images of the openings after each number of laser beam irradiations shown in FIGS. 7A to 7D, the investigations whose results are shown in FIG. 6A to FIG. 6D were respectively conducted for separate opening formations.

FIG. 6A shows the sensor outputs (SO) measured for five repeated laser beam irradiations. FIGS. 6B, 6C, and 6D respectively show the sensor outputs (SO) measured for eight, eleven, and fourteen repeated laser beam irradiations. Therefore, FIGS. 7A, 7B, 7C, and 7D are observation images of the openings formed by five, eight, eleven, and fourteen repeated laser beam irradiations, respectively. The investigations whose results are shown in FIGS. 6A to 6D and FIGS. 7A to 7D were conducted by irradiating an 8.5 μm thick insulating layer covering a 2.5 μm thick conductor layer with a pulsed laser beam having a wavelength of 355 nm and an energy density of 0.82 J/cm². The pulse width of the laser beam was 10 nsec, and the pulse frequency was 200 kHz.

As shown in FIG. 6A, for up to five repeated laser beam irradiations, the level of the sensor output (SO) for each irradiation is approximately 0 V. In other words, as shown in FIG. 7A, the opening (S31) formed in the insulating layer (S2) by five repeated laser beam irradiations does not penetrate the insulating layer (S2), so no plasma light is emitted from the wiring substrate (S), or even when plasma light is faintly emitted, that plasma light contains substantially no wavelength component specific to copper or other materials constituting the conductor layer (S1). Therefore, since substantially no light reaches the sensor 6 illustrated in FIG. 1, only a sensor output (SO) of approximately 0 V is measured.

In the measurement results shown in FIG. 6B, a substantial level of sensor output (SO) is measured for the last two laser beam irradiations. For the last laser beam irradiation, a sensor output (SO) level of approximately 0.2 V is measured. Referring to FIG. 7B, an opening (S31) reaching the conductor layer (S1) is formed by eight repeated laser beam irradiations, with the surface of the conductor layer (S1) slightly exposed in the opening (S31). Therefore, plasma light is emitted from the wiring substrate (S). This plasma light contains a wavelength component specific to copper or the like constituting the conductor layer (S1), and since light of these wavelength components reaches the sensor 6 in FIG. 1, a sensor output (SO) greater than 0 V is measured. In the laser beam irradiations for which the sensor outputs (SO) are shown in FIG. 6B, as shown in FIG. 4B previously referred to, the irradiation site of the laser beam (LB) is thought to be near the interface between the insulating layer (S2) and the conductor layer (S1).

In the measurement results shown in FIG. 6C, the level of the sensor output (SO) rises to approximately 0.4 V for the last two irradiations. Referring to FIG. 7C, at the bottom surface of the opening (S31) that has reached the conductor layer (S1), the conductor layer (S1) is exposed over a larger area compared to the exposed area of the conductor layer (S1) in FIG. 7B. Therefore, the intensity of the plasma light emitted from the wiring substrate (S) is higher than that during the irradiations for which the sensor outputs are shown in FIG. 6B, and since the emitted plasma light contains a wavelength component specific to copper or the like constituting the conductor layer (S1), the results shown in FIG. 6C show a higher level of sensor output (SO) than that in FIG. 6B.

Then, in the measurement results shown in FIG. 6D, sensor outputs (SO) with even higher levels than those of the measurement results shown in FIG. 6C are measured. Referring to FIG. 7D, at the bottom surface of the opening (S31), although somewhat difficult to discern, as described later, the conductor layer (S1) is exposed over a larger area compared to the exposed area of the conductor layer (S1) in FIG. 7C. Therefore, the results shown in FIG. 6D show sensor outputs with even higher levels than those in FIG. 6C. For the final irradiations among the laser beam irradiations for which the sensor outputs (SO) are shown in FIGS. 6C and 6D, similar to the processing state illustrated in FIG. 3 referred to above, the irradiation site of the laser beam is thought to be primarily the conductor layer.

In observing the openings (S31) whose images are shown in FIGS. 7A to 7D, the opening diameter and opening area at the bottom surface of each opening (S31) were measured using a measurement function of an observation device. The opening diameters at the bottom surfaces of the openings (S31) shown in FIGS. 7A, 7B, 7C, and 7D were 0 μm, approximately 4.2 μm, approximately 6.4 μm, and approximately 7.0 μm, respectively. Further, the opening areas at the bottom surfaces of the openings (S31) shown in FIGS. 7A, 7B, 7C, and 7D were 0 μm², approximately 13.8 μm², approximately 35.8 μm², and approximately 40.4 μm², respectively.

From the investigations whose results are shown in FIGS. 6A to 6D and FIGS. 7A to 7D, it is evident that by continuing laser beam irradiation even after the laser beam begins to irradiate the conductor layer in the wiring substrate, which is the processing target, an opening with a larger opening area at the bottom surface can be formed. It is thought that an opening with a bottom surface area closer to a desired opening area can be formed.

### Correlation Between Sensor Output Integrated Value and Opening Area of Opening

FIG. 8 illustrates a relationship between the sensor output integrated value (horizontal axis) for each processing position and the opening area at the bottom surface of the opening formed at the processing position (vertical axis), obtained by irradiating a pulsed laser beam 5 to 14 times at each of many processing positions on the wiring substrate. The pulsed laser beam was irradiated at a constant cycle and with a constant irradiation time (pulse width) for each irradiation. The sensor output integrated value shown on the horizontal axis of FIG. 8 is the integrated value obtained for each processing position by summing the product of the sensor output for each irradiation and the unit time corresponding to the irradiation cycle of the pulsed laser beam across all sensor outputs. In FIG. 8, the differences in the number of irradiations from 5 to 14 are distinguished by different symbols (such as ◯ and Δ). From the results shown in FIG. 8, it is evident that there exists a specific relationship, approximated by a straight line (L), between the sensor output integrated value obtained for the repetitive pulsed laser beam irradiations and the opening area at the bottom surface of the opening formed by the repetitive irradiations.

Since the existence of such a relationship, as exemplified in FIG. 8, has been identified, as described above, when the sensor output integrated value satisfies the “predetermined condition,” it can be deemed that an opening with a desired opening area has been formed, and the processing by laser beam irradiation can be stopped immediately or after a predetermined time has elapsed. In other words, the sensor output integrated value can be used to determine when to stop the processing by laser beam irradiation for forming the opening.

Therefore, the arithmetic part 51 of the control device 5 (see FIG. 1) may calculate the product of the irradiation cycle of multiple laser beam irradiations at a constant cycle at one processing position and the sensor output for each irradiation of the laser beam, and calculate the sum (total value) of these products from the start of processing at the one processing position as the sensor output integrated value. In other words, the sensor output integrated value may be, for example, the sum obtained by summing the product of the sensor output for each irradiation of multiple laser beam irradiations at a constant cycle at one processing position and the unit time corresponding to the irradiation cycle of the laser beam, across all sensor outputs from the start of processing at the one processing position.

Even when the horizontal axis of FIG. 8 represents the sum of the sensor outputs themselves, it is thought that a specific relationship exists between the sum (integrated value) and the opening area at the bottom surface of the opening, for example, with only the slope of the straight line (L) changing. Accordingly, the control device 5 may be structured to calculate, for example, through the arithmetic part 51, as the sensor output integrated value, the sum (total value) of the sensor outputs for the multiple laser beam irradiations at one processing position from the start of processing at that one processing position.

In the repetitive laser beam irradiations, the irradiation time or irradiation cycle for the irradiations does not need to be constant. Even in this case, it is thought that the sum of the products of the irradiation time of each of the multiple laser beams and the sensor output during the respective irradiation time, from the start of processing, has a specific relationship with the opening area of the opening formed by the multiple laser beam irradiations, similar to that shown in FIG. 8.

Therefore, the control device 5 may be structured to calculate, for example, through the arithmetic part 51, the product of the irradiation time for each of multiple laser beam irradiations at one processing position and the sensor output during the respective irradiation time, and calculate the sum (total value) of these products from the start of processing at the one processing position as the sensor output integrated value. In other words, the sensor output integrated value may be, for example, the sum obtained by summing the product of the sensor output for each irradiation of multiple laser beam irradiations at one processing position and the irradiation time of each irradiation, across all sensor outputs from the start of processing at the one processing position. When the control device 5 calculates the sensor output integrated value in this way, the degree of freedom in setting a temporal condition for the multiple laser beam irradiations may be increased. Further, since specific irradiation times are incorporated into the calculation, it may be possible to form an opening with a bottom surface area closer to a desired opening area with greater accuracy.

Further, from the results shown in FIG. 8, it is thought that the determination to stop processing for forming an opening by laser beam irradiation may use a definite integral value of a time-dependent function of the sensor output obtained for each irradiation of repetitive laser beam irradiations. In other words, the relationship between the sensor output obtained for each irradiation of repetitive pulsed laser beam irradiations, as shown in FIGS. 6A to 6D, and the elapsed time from the start of irradiation is approximated by a function of an appropriate degree. Further, the definite integral value of that function with respect to the elapsed time up to each irradiation of the repetitive irradiations is calculated, and a specific relationship, such as that exemplified in FIG. 8, between each definite integral value and the opening area of the opening formed up to each irradiation is identified. Then, based on this identified relationship, the definite integral value of the sensor output, as the sensor output integrated value, may be used to determine when to stop processing by the laser beam irradiation for forming the opening.

Therefore, in the laser processing device of the embodiment, the control device 5 may be structured to derive a mathematical expression (function) representing the relationship between the sensor output obtained for each irradiation of repetitive laser beam irradiations and the elapsed time from the start of irradiation. Further, the control device 5 may be structured to calculate, for the derived mathematical expression, a definite integral value from the start of the repetitive laser beam irradiations to the time of each irradiation as the sensor output integrated value. Then, the determination part 53 (see FIG. 1) may be structured to determine whether or not the definite integral value, calculated as the sensor output integrated value, satisfies the above-described “predetermined condition.”

### Laser Processing Method

The laser processing method of the embodiment primarily includes, as processes to be executed, several operations, controls, and electrical or optical processes performed by the structural components such as the control device of the laser processing device of the embodiment. The laser processing method of the embodiment may be performed using the laser processing device of the embodiment or may be performed without using the laser processing device of the embodiment. In the following, the laser processing method of the embodiment will be described, taking as an example the case where the laser processing device 1 of the embodiment is used, with reference again to FIG. 1 and the like and using the reference numeral symbols assigned in FIG. 1. Unless specifically mentioned otherwise in the following description, the operations, controls, and various processes and the like performed by the structural elements described with respect to the laser processing device of the embodiment may be included in the laser processing method of the embodiment.

The laser processing method of the embodiment is a laser processing method for a wiring substrate such as the wiring substrate (S) illustrated in FIG. 1. The laser processing method of the embodiment includes forming an opening (S31) in an insulating layer (S2) of the wiring substrate (S) to expose a portion of a conductor layer (S1) covered by the insulating layer (S2) by irradiating a surface of the wiring substrate (S) with a laser beam (LB). The laser processing method of the embodiment further includes causing the sensor 6 to output a sensor output (SO) based on plasma light (PL)emitted from the wiring substrate (S) due to the irradiation of the laser beam (LB) by allowing the plasma light (PL) to enter the sensor 6.

In other words, in the implementation of the laser processing method of the embodiment, when the laser processing device 1 of FIG. 1 is used, a laser beam (LB), for example, in the UV band and in a pulsed form, is emitted from the light source 2. The laser beam (LB) irradiates the surface of the wiring substrate (S) via the AOM 7, the beam splitter 4, the galvanometer mirror unit 8, and the objective lens 3. By irradiating a predetermined location on the wiring substrate (S) with the laser beam (LB), an opening (S31) can be formed at the predetermined location. When the laser beam (LB) irradiates the conductor layer (S1), plasma light (PL) containing light of a wavelength specific to the constituent material of the conductor layer (S1) is emitted. The plasma light (PL) enters the beam splitter 4 via the objective lens 3 and the galvanometer mirror unit 8. Among the plasma light (PL), at least the plasma light (PL) having a wavelength specific to the constituent material of the conductor layer (S1) is reflected by the beam splitter 4 in the second direction (D2), passes through the filters (61, 62), and enters the sensor 6. The sensor 6 outputs a sensor output (SO) with a level corresponding to, for example, the intensity of the incident light.

As described with respect to the laser processing device of the embodiment, the intensity of the plasma light (PL) changes in according to a change in the constituent material of the wiring substrate (S) irradiated by the laser beam (LB), and further, the sensor output (SO) also changes. Further, the integrated value of the sensor output (SO) (sensor output integrated value), calculated for multiple irradiations of a pulsed laser beam (LB) at the same position on the wiring substrate (S), which is the processing target, has a specific relationship with the opening area at the bottom surface of the formed opening (S31). To utilize this relationship, the laser processing method of the embodiment further includes calculating the sensor output integrated value.

In other words, forming the opening (S31) in the laser processing method of the embodiment includes repeating the irradiation of, for example, a pulsed laser beam (LB) multiple times at one processing position on the wiring substrate (S). Further, forming the opening (S31) in the laser processing method of the embodiment includes calculating the sensor output integrated value, which is the integrated value of the sensor outputs (SO) of the multiple irradiations of the laser beam (LB) from the start of processing at the one processing position. Then, in the laser processing method of the embodiment, forming the opening (S31) further includes terminating the formation of the opening (S31) at the one processing position by the irradiation of the laser beam (LB) when the sensor output integrated value satisfies a predetermined condition. Since the opening (S31) is formed through such processes, as described with respect to the laser processing device of the embodiment, it is thought that an opening (S31) with a bottom surface area closer to a desired opening area can be formed.

In the laser processing method of the embodiment, as an example, when the sensor output integrated value satisfies a predetermined condition, the formation of the opening (S31) at the processing position at that moment may be terminated by immediately stopping the irradiation of the laser beam (LB). As another example, when the sensor output integrated value satisfies a predetermined condition, the irradiation of the laser beam (LB) may be continued for a predetermined time to ensure the formation of an opening (S31) with a desired opening area, and then the irradiation may be stopped, thereby terminating the formation of the opening (S31) at the processing position at that moment.

As an example, the “predetermined condition” may be that the sensor output integrated value reaches a predetermined first threshold. In other words, the predetermined condition may be satisfied when the sensor output integrated value reaches a predetermined first threshold. The “predetermined first threshold” may be, for example, a value of the sensor output integrated value corresponding to a median of an allowable range for the opening area at the bottom surface of the opening (S31). By terminating the formation of the opening at the processing position being irradiated with the laser beam (LB) when the sensor output integrated value reaches the predetermined first threshold, it is thought possible to form an opening with a bottom surface area close to a desired opening area. Further, as another example, the “predetermined condition” may be that the unit increase rate of the sensor output integrated value falls within a range of a predetermined second threshold. In this case, the “predetermined second threshold” may be, for example, 40% or more and 60% or less.

In the laser processing method of the embodiment, the sensor output integrated value may be a simple sum of the sensor outputs (SO) from the start of processing at the one processing position. Therefore, in the laser processing method of the embodiment, calculating the sensor output integrated value may include calculating the sum of the sensor outputs (SO) for the multiple irradiations of the laser beam (LB) at one processing position, from the start of processing at that one processing position.

Further, the sensor output integrated value may be the sum obtained by summing the product of the sensor output (SO) for each irradiation of multiple laser beam (LB) irradiations at one processing position and the unit time corresponding to the irradiation cycle, across all sensor outputs (SO) from the start of processing at the one processing position. When multiple irradiations of the laser beam (LB) are repeated with a constant cycle and a constant irradiation time for each irradiation, the sensor output integrated value may be the sum of the products of the sensor output (SO) for each irradiation and the irradiation cycle. Therefore, in the laser processing method of the embodiment, calculating the sensor output integrated value may include calculating the product of the irradiation cycle of multiple laser beam (LB) irradiations at a constant cycle at one processing position and the sensor output (SO) for each irradiation of the laser beam (LB), and computing the sum of these products from the start of processing at the one processing position.

Further, the sensor output integrated value may be the sum obtained by summing the product of the sensor output (SO) for each irradiation of multiple laser beam (LB) irradiations at one processing position and the irradiation time of each irradiation, across all sensor outputs (SO) from the start of processing at the one processing position. Therefore, in the laser processing method of the embodiment, calculating the sensor output integrated value may include calculating the sum of the products of the irradiation time for each of multiple laser beam (LB) irradiations at one processing position and the sensor output (SO) during the respective irradiation time, from the start of processing at that one processing position.

Further, as described with respect to the laser processing device of the embodiment, the sensor output integrated value may be a definite integral value of a time-dependent function of the sensor output (SO) obtained for each irradiation of multiple repetitive laser beam (LB) irradiations. Therefore, in the laser processing method of the embodiment, calculating the sensor output integrated value may include deriving a mathematical expression (function) representing the relationship between the sensor output (SO) obtained for each irradiation of multiple laser beam (LB) irradiations and the elapsed time from the start of the multiple irradiations, and calculating a definite integral value of the derived mathematical expression up to the time of each irradiation.

### Understanding Correlation Between Sensor Output Integrated Value and Opening Area

The laser processing method of the embodiment may further include understanding in advance the correlation between the sensor output integrated value and the opening area at the bottom surface of the formed opening, as shown in FIG. 8 referred to above. In other words, the laser processing method of the embodiment may preferably include repeating the irradiation of a test laser beam multiple times at the same position on a wiring substrate composed of the same structure and materials as the wiring substrate to be processed (Process A), and obtaining the opening area at the bottom surface of the opening formed at that same position after each of the multiple irradiations of the test laser beam (Process B).

The laser processing method of the embodiment may further include obtaining a reference integrated value by integrating the sensor output for each of multiple irradiations of the test laser beam at the same position from the start of the test laser beam irradiation (Process C). The correlation between the reference integrated value up to each irradiation of the multiple test laser beam irradiations and the opening area obtained in Process B after each irradiation is thought to directly indicate the correlation between the opening area at the bottom surface of the opening formed by the laser processing method of the embodiment and the sensor output integrated value.

Therefore, the laser processing method of the embodiment may further include setting a “predetermined condition” as a condition for terminating processing at one processing position based on the correlation between the opening area obtained in Process B and the reference integrated value obtained in Process C (Process D). For example, based on the correlation between the opening area obtained in Process B and the reference integrated value, a “first threshold” may be set, which is a criterion for determining the termination of processing at one processing position with respect to the sensor output integrated value.

The understanding of the correlation between the reference integrated value and the opening area of the formed opening may be performed using the laser processing device 1 of the embodiment illustrated in FIG. 1. For the test laser beam, preferably, a laser beam having substantially the same processing capability as the laser beam used for processing the wiring substrate in the laser processing method of the embodiment is used with respect to an insulating layer of a wiring substrate to be processed, such as the wiring substrate (S).

As described above, in the laser processing device and laser processing method of the embodiment, by using the sensor output integrated value to determine the termination of processing, it is thought possible to form an opening with a bottom surface area closer to a desired opening area compared to a conventional laser processing device or method. Further, it is thought that damage to the conductor layer due to unnecessarily prolonged irradiation of the laser beam can be reduced. For example, it is thought that issues such as penetration of the conductor layer due to excessive continuation of laser beam irradiation can be prevented.

With the progress in miniaturization of wiring patterns in wiring substrates, small-diameter via conductors are desired. Small-diameter via conductors require small-diameter openings, and for forming small-diameter openings, the use of a short-wavelength, short-pulse laser beam may be preferable. On the other hand, a short-wavelength, short-pulse laser beam has high processing capability for copper, so excessive continuation of laser beam irradiation tends to cause excessive damage to the conductor layer. In contrast, in the laser processing device and laser processing method of the embodiment, the sensor output integrated value, which has a specific relationship with the opening area of the formed opening, is used to determine the termination of the processing for forming the opening. Therefore, it is thought that laser beam irradiation with minimal excess or deficiency can be achieved. In other words, it is thought that the conductor layer is unlikely to sustain excessive damage. Therefore, the laser processing device and laser processing method of the embodiment may be particularly suitable for forming small-diameter via conductors and, further, for manufacturing wiring substrates having fine wiring patterns.

The laser processing device of the embodiment is not limited to those having the structure exemplified in FIG. 1 or the structures exemplified in the present specification. For example, the functions of filters (61, 62) may be incorporated into the beam splitter 4 or the sensor 6. Further, the laser processing device of the embodiment may include any structural elements other than those illustrated in FIG. 1. Further, the laser processing method of the embodiment is not limited to the method described with reference to FIG. 1. The laser processing method of the embodiment may include any additional processes beyond those described above, and some of the processes described above may be omitted.

Japanese Patent Application Laid-Open Publication No. 2013-43198 describes a drilling method and a laser processing device for forming a laser-processed hole that reaches from a first member to a second member by irradiating, with a laser beam, a workpiece composed of the first member and the second member that are connected. In the method and processing device described in Japanese Patent Application Laid-Open Publication No. 2013-43198, a minimum value and a maximum value are set in advance for the number of shots of the pulsed laser beam. The irradiation of the pulsed laser beam is stopped based on a magnitude relationship between the minimum and maximum values and the number of shots of the pulsed laser beam already irradiated, and based on a change in the spectrum emitted by plasma generated by the irradiation of the pulsed laser beam.

In the drilling method and laser processing device described in Japanese Patent Application Laid-Open Publication No. 2013-43198, the irradiation of the pulsed laser beam is stopped when there is a change in the spectrum of the plasma or when the number of irradiations of the pulsed laser beam reaches a preset number of shots. Therefore, the laser-processed hole may not necessarily have a desired opening area.

A laser processing device according to an embodiment of the present invention is for forming an opening in an insulating layer of a wiring substrate to expose a portion of a conductor layer covered by the insulating layer, and includes: a light source that emits a laser beam; an objective lens that focuses the laser beam onto a surface of the wiring substrate; a control device that controls irradiation of the laser beam; and a sensor that outputs to the control device a sensor output based on plasma light emitted from the wiring substrate due to the irradiation of the laser beam. The control device is structured to calculate, for the sensor output corresponding to each of multiple irradiations of the laser beam at one processing position on the wiring substrate, an integrated value from start of processing at the one processing position, and to terminate the formation of the opening at the one processing position by the irradiation of the laser beam when the integrated value satisfies a predetermined condition.

A laser processing method according to another embodiment of the present invention is for a wiring substrate, and includes: forming an opening in an insulating layer of the wiring substrate to expose a portion of a conductor layer covered by the insulating layer by irradiating a surface of the wiring substrate with a laser beam; and causing a sensor to output a sensor output based on plasma light emitted from the wiring substrate due to the irradiation of the laser beam by allowing the plasma light to enter the sensor. The forming of the opening includes: repeating the irradiation of the laser beam multiple times at one processing position on the wiring substrate; calculating, for the sensor output corresponding to each of multiple irradiations of the laser beam, an integrated value from start of processing at the one processing position; and terminating the formation of the opening at the one processing position by the irradiation of the laser beam when the integrated value satisfies a predetermined condition.

According to an embodiment of the present invention, it is thought that an opening with a bottom surface area closer to a desired opening area can be formed in an insulating layer of a wiring substrate.

Obviously, numerous modifications and variations of the present invention are possible in light of the above teachings. It is therefore to be understood that within the scope of the appended claims, the invention may be practiced otherwise than as specifically described herein.

1. A laser processing device for forming an opening in an insulating layer of a wiring substrate, comprising:
a light source that emits a laser beam;
an objective lens configured to focus the laser beam onto a surface of a wiring substrate;
a control device comprising circuitry configured to control irradiation of the laser beam; and
a sensor that outputs to the control device a sensor output based on plasma light emitted from the wiring substrate irradiated with the laser beam,
wherein the circuitry of the control device is configured to calculate an integrated value from start of processing at one processing position for the sensor output corresponding to each of irradiations of the laser beam at the one processing position on the wiring substrate and terminate formation of the opening at the one processing position when the integrated value satisfies a predetermined condition.

2. The laser processing device according to claim 1, wherein the circuitry of the control device is configured to terminate the formation of the opening at the one processing position when the integrated value reaches a first threshold.

3. The laser processing device according to claim 1, wherein the circuitry of the control device is configured to calculate the integrated value comprising a sum of the sensor output for each of the irradiations of the laser beam at the one processing position from the start of processing.

4. The laser processing device according to claim 1, wherein the circuitry of the control device is configured to calculate the integrated value comprising a sum from the start of processing of products of irradiation time of each of the irradiations of the laser beam at the one processing position and the sensor output during a respective irradiation time.

5. The laser processing device according to claim 1, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

6. The laser processing device according to claim 2, wherein the circuitry of the control device is configured to calculate the integrated value comprising a sum of the sensor output for each of the irradiations of the laser beam at the one processing position from the start of processing.

7. The laser processing device according to claim 2, wherein the circuitry of the control device is configured to calculate the integrated value comprising a sum from the start of processing of products of irradiation time of each of the irradiations of the laser beam at the one processing position and the sensor output during a respective irradiation time.

8. The laser processing device according to claim 2, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

9. The laser processing device according to claim 3, wherein the circuitry of the control device is configured to calculate the integrated value comprising a sum from the start of processing of products of irradiation time of each of the irradiations of the laser beam at the one processing position and the sensor output during a respective irradiation time.

10. The laser processing device according to claim 3, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

11. The laser processing device according to claim 4, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

12. The laser processing device according to claim 6, wherein the circuitry of the control device is configured to calculate the integrated value comprising a sum from the start of processing of products of irradiation time of each of the irradiations of the laser beam at the one processing position and the sensor output during a respective irradiation time.

13. The laser processing device according to claim 6, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

14. The laser processing device according to claim 12, further comprising:
a beam splitter positioned in an optical path between the light source and the objective lens; and
a filter positioned between the beam splitter and the sensor and having a stop band including a wavelength of the laser beam,
wherein the beam splitter transmits the laser beam and reflects the plasma light emitted from the wiring substrate such that the plasma light is deflected from the optical path of the laser beam.

15. A laser processing method for a wiring substrate, comprising:
irradiating an insulating layer of a wiring substrate with a laser beam such that an opening is formed in the insulating layer and exposes a portion of a conductor layer covered by the insulating layer; and
causing a sensor to output a sensor output based on plasma light emitted from the wiring substrate irradiated with the laser beam,
wherein the irradiating includes repeating irradiation of the laser beam a plurality of times at one processing position on the wiring substrate, calculating an integrated value from a start of processing at one processing position for the sensor output corresponding to the irradiation of each of the times, and terminating formation of the opening at the one processing position when the integrated value satisfies a predetermined condition.

16. The laser processing method according to claim 15, wherein the predetermined condition is satisfied when the integrated value reaches a first threshold.

17. The laser processing method according to claim 15, wherein the calculating of the integrated value includes calculating a sum of the sensor output for the irradiation of each of the times at the one processing position from the start of processing.

18. The laser processing method according to claim 15, wherein the calculating of the integrated value includes calculating a sum from the start of processing of products of irradiation time of the irradiation of each of the times at the one processing position and the sensor output during a respective irradiation time.

19. The laser processing method according to claim 15, further comprising:
repeating irradiation of a test laser beam a plurality of times at a same position on the wiring substrate;
obtaining an opening area of an opening formed at the same position after each irradiation of the test laser beam;
integrating the sensor output for each irradiation of the test laser beam at the same position from a start of the irradiation of the test laser beam such that a reference integrated value is obtained; and
setting the predetermined condition based on a correlation between the opening area and the reference integrated value.

20. The laser processing method according to claim 16, wherein the calculating of the integrated value includes calculating a sum of the sensor output for the irradiation of each of the times at the one processing position from the start of processing.
